(19) United States
(12) Patent Application Publication
(10) Pub. No.: US 2012/0177895 A1
(43) Pub. Date: Jul. 12, 2012

(54) METHOD OF PATTERNING METAL AND ASSEMBLY FOR FORMING A PATTERNED METAL FILM

(75) Inventors: Suk Jun KIM, Suwon-si (KR); Young Hun BYUN, Seoul (KR); Jae Ho LEE, Yongin-si (KR); Yun Hyuk CHOI, Seoul (KR)

(73) Assignee: SAMSUNG ELECTRONICS CO., LTD., Suwon-si (KR)

(21) Appl. No.: 13/289,768

(22) Filed: Nov. 4, 2011

(30) Foreign Application Priority Data
Jan. 12, 2011 (KR) 10-2011-0003057

(51) Int. Cl. B32B 3/10; H05K 3/12; H01L 21/768; B32B 15/08

(52) U.S. Cl. 428/201; 427/97.3; 438/652; 257/E21.582

(57) ABSTRACT

A method of patterning a metal to form a patterned metal film. The method includes patterning a surface-treating composition including a polymer and a reductant on a surface of a substrate; and applying a metal source onto the substrate to form a patterned metal film.

### CROSS-REFERENCE TO RELATED APPLICATION

This application claims priority to Korean Patent Application No. 10-2011-0003057, filed on Jan. 12, 2011, and all the benefits accruing therefrom under 35 U.S.C. §119, the content of which in its entirety is herein incorporated by reference.

### BACKGROUND

1. Field

The disclosure relates to a method of patterning a metal and an assembly for forming a patterned metal film.

2. Description of the Related Art

A metal patterning process is widely used in products having printed surfaces, such as electronic products, display devices, touch screen panels, and solar cells. Recently, as demands for metal patterns having narrower linewidths have increased, related research has been actively performed.

In general, the metal patterning process may include applying an ink or paste, which includes a metal powder, nanoparticles, or metal oxide particles dispersed in a solvent, onto a substrate, or applying a solution of a metal ion or metal compound onto a substrate.

However, after the ink or solution is applied onto the substrate, dewetting may occur due to a difference in surface energy between the ink or the solution and the substrate at room temperature or during a sintering process. Thus, a patterned metal film may not have a desired position, width, and/or thickness.

Also, the linewith of a commercially available patterned metal film is about 20 micrometers (μm) or less. Thus, there remains a need for a patterned metal film with a narrower linewidth, such as a linewidth of about 10 μm or less.

### SUMMARY

Exemplary embodiments provide a method of patterning a metal by which a patterned metal film is formed on the surface of a substrate using a surface-treating composition containing a polymer and a reductant.

According to an exemplary embodiment, a method of patterning a metal to form a patterned metal film includes: patterning a surface-treating composition including a polymer and a reductant on a surface of a substrate; and applying a first metal source onto the substrate to form the patterned metal film.

In the surface-treating composition, the polymer and the reductant may be bonded to each other.

The first metal source may include a precursor ink which includes a metal, and the first metal source may be applied onto a portion of the surface of the substrate where the surface-treating composition is patterned (e.g., disposed).

The method may further include reducing the patterned metal film.

The method may further include applying a second metal source onto the patterned metal film and sintering the metal source.

The second metal source may be applied on at least one selected from an entire surface of the substrate, a portion of the substrate where the surface-treating composition is patterned, and the patterned metal film.

According to another exemplary embodiment, an assembly for forming a patterned metal film includes: a substrate; a surface-treating composition patterned on the substrate; and a first metal source disposed on the surface-treating composition.

The first metal source may form a metal layer on a portion of the substrate where the surface-treating composition is patterned.

### BRIEF DESCRIPTION OF THE DRAWINGS

The above and other aspects of this disclosure will become more readily apparent by describing in further detail non-limiting example embodiments thereof with reference to the accompanying drawings, in which:

FIG. 1 is a schematic diagram illustrating an embodiment of a method of patterning a metal;

FIG. 2 is a schematic diagram illustrating another embodiment of a method of patterning a metal;

FIGS. 3A to 3C are images showing an embodiment of a patterned metal film produced according to Example 1;

FIGS. 4A and 4B are images showing an embodiment of a patterned metal film produced according to Example 2;

FIGS. 5A and 5B are images showing an embodiment of a patterned metal film produced according to Example 3; and

FIG. 6 is an image showing an embodiment of a patterned metal film produced according to Comparative Example 1.

### DETAILED DESCRIPTION

The invention now will be described more fully hereinafter with reference to the accompanying drawings, in which a non-limiting embodiment is shown. This invention may, however, may be embodied in many different forms, and should not be construed as limited to the embodiments set forth herein. Rather, these embodiments are provided so that this disclosure will be thorough and complete, and will fully convey the scope of the invention to those of ordinary skill in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the present invention.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises” and/or “comprising,” or “includes” and/or “including” when used in this specification, specify the presence of stated regions, integers, steps, operations, elements, and/or components, but do not preclude the presence or addition of one or more other regions, integers, steps, operations, elements, components, and/or groups thereof.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

According to an exemplary embodiment, a method of patterning a metal may comprise: patterning a surface-treating composition comprising a polymer and a reductant on a surface of a substrate; and applying a first metal source onto the surface of the substrate to pattern the metal. The patterned metal may be in the form of a film. The method may further comprise applying a second metal source onto the patterned metal film and sintering the second metal source. The first and second metal sources may be the same of different.

### Method of Patterning

A surface-treating composition comprising a polymer and a reductant may be patterned (e.g., disposed in a selected pattern) on the surface of a substrate.

The polymer is a polymer that adheres to the substrate, and may comprise a hydrophilic polymer, a hydrophobic polymer, or an amphipathic polymer. For example, the polymer may be ethyl cellulose, polystyrene, or polyvinyl pyrrolidone (“PVP”), but is not limited thereto. The polymer may be in the form of a simple polymer shape, a bead shape, or a porous shape, but is not limited thereto.

The reductant may comprise a material that comprises a moiety which may be combined with, mixed, or bonded with the polymer, and that can reduce a metal ion or a metal precursor contained in the first and/or the second metal source. The reductant may include, for example, at least one selected from hydrazine, lithium aluminum hydride, alkyl aluminum hydride, sodium borohydride, zinc borohydride, trialkyl tin hydride, alkyl silane, a combination thereof, and a complex thereof, but is not limited thereto. In the surface-treating composition, the polymer and the reductant may be simply mixed, or bonded with each other.

When the polymer and the reductant are simply mixed in the surface-treating composition, the polymer and the reductant may be mixed in a weight ratio of about 1:10 to about 1:0.01, or about 1:5 to about 1:0.05, or about 1:1 to about 1:0.1. Within the foregoing weight-ratio range, the reductant may not separate from the polymer and may be sufficiently mixed with the polymer to form a uniform film so that metal ions can be uniformly reduced throughout the film.

When the reductant and the polymer are bonded with each other, the reductant and the polymer may be covalently or ionically bonded. For example, the reductant and the polymer may be directly bonded or indirectly bonded by a linker which is bonded with both the reductant and the polymer. Representative examples of the linker include, for example, ethylene diamine, dialcohol amine, or pyridine. For example, the reductant and the polymer may have a structure according to at least one of the following Formulas 1 to 3, but is not limited thereto.

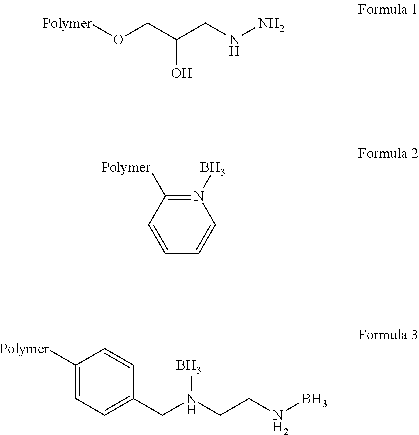

In Formulas 1 to 3, the polymer may include at least one selected from a hydrophilic polymer, a hydrophobic polymer, and an amphipathic polymer.

A bonding structure of the reductant and the polymer and a method of preparing the same can be understood and determined by one of ordinary skill in the art without undue experimentation from known documents, for example, i) Journal of Applied Polymer Sciences, 2000, vol. 82, 593-600, ii) Journal of Organic Chemistry, 1980, vol. 45, 2724-2725, and iii) Journal of Polymer Science, 2002, vol 40, 748-754, the contents of which, in their entirety, are herein incorporate by reference.

The surface-treating composition may further include a solvent which is able to be blended with (e.g., combined with) the polymer or the reductant. For example, the solvent may include at least one selected from water, an amine, an ester, a ketone, an aliphatic or aromatic hydrocarbon, an ether, an alcohol, a polyol, an amide, a sulfone, a sulfoxide, and a combination thereof. The amine may be selected from a primary amine such as propylamine, n-butylamine, hexylamine, or octylamine; a secondary amine such as diisopropylamine or di(n-butyl)amine; a tertiary amine such as trioctyl amine or tri-n-butylamine; an alkyl amine such as ethylamine, propylamine, butylamine, hexylamine, octylamine, or trioctyl amine; a cyclic amine, and an aromatic amine. The ester may be selected from polyethylene glycol methacrylate (“PEGMFA”), ethyl acetate, N-butyl acetate, gamma butyrolactone, 2,2,4-trimethyl pentanediol-1,3-monoisobutyrate, butyl carbitol acetate, butyl oxalate, dibutyl phthalate, dibutyl benzoate, butyl cellosolve acetate, ethylene glycol diacetate, and ethylene glycol diacetate. The ketone may be selected from acetone, methylethyl ketone, methyl isobutyl ketone, and cyclohexanone. The aliphatic or aromatic hydrocarbon may be selected from toluene, xylene, aromasol, chlorobenzene, hexane, cyclohexane, decane, dodecane, tetradecane, hexadecane, octadecane, octadecene, nitrobenzene, and o-nitrotoluene. The ether may be selected from diethyl ether, dipropyl ether, dibutyl ether, dioxane, tetrahydrofuran, octyl ether, and tri(ethylene glycol) dimethyl ether. The alcohol may be selected from methanol, ethanol, 1-propanol, 2-propanol, 1-butanol, 2-butanol, isobutanol, hexanol, isopropyl alcohol, ethoxy ethanol, ethyl lactate, octanol isopropyl alcohol, ethylene glycol monomethyl ether, benzyl alcohol, 4-hydroxy-3 methoxy benzaldehyde, isodeconol, butyl carbitol, terpineol, alpha terpineol, beta-terpineol, and cineol. The polyol solvent may be selected from glycerol, glycol, ethylene glycol, diethylene glycol, triethylene glycol, tetraethylene glycol, propylene glycol, dipropylene glycol, butanediol, hexylene glycol, 1,2-pentanediol, 1,2-hexanediol, glycerin, polyethylene glycol, polypropylene glycol, ethylene glycol monomethyl ether (methyl cellosolve), ethylene glycol monoethyl ether (ethyl cellosolve), ethylene glycol monobutyl ether (butyl cellosolve), diethylene glycol monoethyl ether, and diethylene glycol monobutyl ether. The amide may be N-methyl-2-pyrrolidone (“NMP”), 2-pyrrolidone, N-methyl formamide, N,N-dimentyl formamide, and N,N-dimethyl acetamide. The sulfone or sulfoxide may be selected from diethyl sulfone, tetramethylene sulfone, dimethyl sulfoxide, and diethyl sulfoxide. The solvent may be added in an appropriate amount to the surface-treating composition such that the concentration of the polymer and the reductant is about 0.1 to about 90% by weight, or about 1 to about 80% by weight, or about 10 to about 70% by weight, based on the total weight of the surface-treating composition.

The substrate may be a substrate which adheres to the polymer or the combination comprising the polymer and the reductant, e.g., the surface-treating composition. For example, the substrate may comprise at least one selected from a glass, a metal, a semiconductor, a ceramic, and a plastic, but is not limited thereto.

A method of patterning the surface-treating composition on the substrate is not especially limited. For example, the surface-treating composition may be printed, sprayed, or coated on the surface of the substrate in a specific pattern. When disposed on the substrate, the surface-treating composition may be have a thickness of about 100 to about 0.5 micrometer (μm), or about 90 to about 1 μm, or about 80 to about 2 μm, and a linewidth of the surface-treating composition may be about 10 μm or less, for example, about 0.5 to about 10 μm, about 1 μm or less, or about 1 to about 5 μm, but is not limited thereto.

Before the patterning of the surface-treating composition on the substrate, the method may further comprise washing the surface of the substrate. For example, the substrate may be washed using water.

### Method of Forming a Patterned Metal Film

The patterned metal film may be formed by applying the first metal source onto the surface of the substrate.

The first and the second metal sources may each independently comprise a metal ion that may be reduced by the reductant. The first and the second metal sources may each independently comprise at least one selected from gold (Au), silver (Ag), nickel (Ni), indium (In), zinc (Zn), titanium (Ti), copper (Cu), chromium (Cr), tantalum (Ta), tungsten (W), platinum (Pt), iron (Fe), cobalt (Co), and an alloy thereof, and a combination thereof, but is not limited thereto. The metal of the first and the second metal sources may each independently be in the form of metal particles or in the form of a metal precursor (e.g., a metal compound or a metal precursor compound) that may be reduced to provide the metal.

As the size of the metal particles decreases, spraying an ink comprising the metal particles through an inkjet nozzle may become easier. Thus, the first and the second metal sources may each independently be in the form of an ink comprising metal nanoparticles, and the metal nanoparticles may have a size (e.g., average largest particle size) of about 500 nm or less, or a size of about 200 nm or less, or a size of about 50 nm or less, or a size of about 500 nm to about 10 nm may be used. The ink may be sprayed to form drops comprising the nanoparticles.

The first and the second metal sources may each independently comprise at least one selected from a metal precursor ink, a metal powder ink, and a metal paste, but is not limited thereto.

The metal precursor ink may be a compound or composition comprising a metal ion which may be reduced to a metal. For example, the metal precursor ink may comprise at least one selected from an organo-metallic compound having a carbon-metal bond, a metal-organic compound comprising an organic ligand and obtained by bonding a non-carbon element such as oxygen, nitrogen, or sulfur with a metal, and an inorganic compound. The inorganic compound may be, for example, a metal nitride, a metal halide, a metal sulfide, a metal hydride, a metal carbonate, or a metal salt, but is not limited thereto. For example, the metal precursor ink may comprise a metal precursor which removes a ligand by a radical mechanism during reduction of the metal precursor to a metal. Also, the metal precursor may comprise a ligand that may be completely removed during the reduction of the metal precursor to the metal. In addition, the metal precursor may be a complex-metal-salt precursor containing a neutral inorganic ligand or organic ligand. For example, the metal precursor may be a nitrate, a halide, a perchlorate, a hydroxide, or a tetrafluoroborate, but is not limited thereto.

In a specific example, the metal precursor may be a metal formate, such as copper formate. The metal formate may be reduced and decomposed by heat, and may generate easily removable volatile materials, such as CO₂, CO, and H₂O, when the metal formate is reduced and decomposed. The volatile materials are gases which, while not wanting to be bound by theory, are understood to protect the metal, e.g., copper, which formed in-situ, from oxidation. The volatile materials may be easily removed, thus remnant impurities are not substantially retained in a resulting copper film. Also, since an aldehyde, which is a reductant, may be generated, the metal ion may be reduced to a metal in high yield using a heating process without using an additional reductant. Furthermore, a decomposition temperature of a metal-organic precursor may be a suitable low temperature, e.g. about 20° C. to about 300° C., or about 50° C. to about 180° C. and thus a highly purity metal film or pattern may be formed at a low temperature.

The first and the second metal sources, e.g., the metal precursor ink or metal powder ink, may each independently further include an additive, such as a stabilizer, a dispersing agent, a binder, a reductant, a surfactant, a wetting agent, a thixotropic agent, a leveling agent, or a conductive material, if desired.

The first metal source may be applied onto the entire surface of the substrate, or may be applied onto a portion of the surface of the substrate where the surface-treating composition is patterned (e.g., disposed). For example, the first metal source may be applied only on the portion of the surface of the substrate where the surface-treating composition is patterned (e.g., disposed). A method of applying the first metal source is not especially limited, but may be performed using a known method, for example, a method selected from a spin coating process, a roll coating process, a deep coating process, a spray coating process, a dip coating process, a flow coating process, a doctor blade process, a dispensing process, an inkjet printing process, a screen printing process, a gravure printing process, an offset printing process, a pad printing process, a flexographic printing process, a stencil printing process, an imprinting process, a xerography process, and a lithographic process.

The first metal source may be reduced by the reductant of the surface-treating composition to form a patterned metal film. To prevent dewetting, the second metal source may be the same as (e.g., may consist of or comprise the same material) as the first metal source that may be applied to the patterned metal film. The method of applying the second metal source is not especially limited, and may also be performed using a known method, for example, a method selected from a spin coating process, a roll coating process, a deep coating process, a spray coating process, a dip coating process, a flow coating process, a doctor blade process, a dispensing process, an inkjet printing process, a screen printing process, a gravure printing process, an offset printing process, a pad printing process, a flexographic printing process, a stencil printing process, an imprinting process, a xerography process, and a lithographic process.

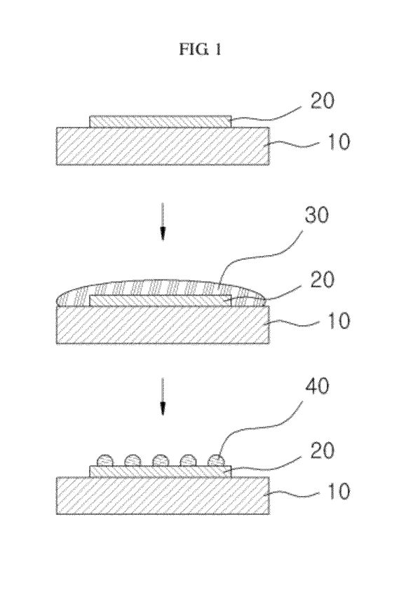

FIG. 1 is a schematic diagram illustrating an embodiment of a method of patterning a metal according to an exemplary embodiment. Referring to FIG. 1, a surface-treating composition 20 may be patterned (e.g., disposed) on the surface of a substrate 10. Thereafter, a first metal source 30 may be applied onto the surface of the substrate 10, and a metal ion contained in the first metal source may be reduced by a reductant, to form a patterned metal film 40.

According to an embodiment, the method of patterning the metal may further include further reducing the patterned metal film. A method of further reducing the metal film is not especially limited, but may be performed by an electroless plating process.

According to an example, the method of patterning the metal may further include applying a second metal source onto the patterned metal film and sintering the second metal source. A detailed description of the second metal source is as above, and will thus not be repeated. The second metal source may be applied onto the entire surface of the substrate, a portion of the substrate where the surface-treating composition is patterned, or on the patterned metal film. For example, the second metal source may be applied onto the patterned metal film. The method of applying and sintering the metal source may be performed by a known method. For example, the second metal source may be applied by a printing process and then sintered under a reducing atmosphere at a temperature of about 180° C. or lower, about 160° C. or lower, about 150° C. or lower, about 130° C. or lower, about 120° C. or lower, or about 100° C. or lower, or at about 50° C. to about 180° C., or about 75° C. to about 160° C.

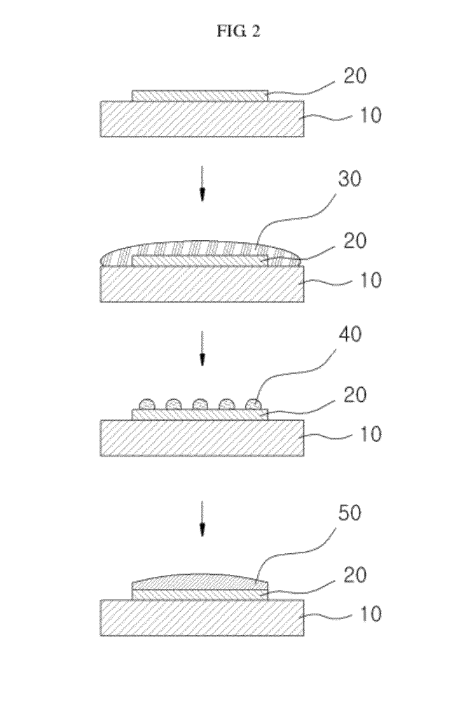

FIG. 2 is a schematic diagram illustrating a method of patterning a metal according to another exemplary embodiment. Referring to FIG. 2, the method of patterning a metal further includes applying a second metal source 50 on a patterned metal film 40 and sintering the second metal source 50. The second metal source 50 may be the same as the first metal source 30. The second metal source 50 may be applied onto the patterned metal film 40 and sintered to form a metal film.

According to an alternative exemplary embodiment, an assembly for forming a patterned metal film may be provided.

An assembly for forming the patterned metal film may include a substrate; a surface-treating composition patterned on the substrate; and a metal source formed on the surface-treating composition.

A detailed description of the substrate, the surface-treating composition, and the metal source are as above.

The first metal source may be applied onto the entire surface of the substrate or a portion of the surface of the substrate where the surface-treating composition is patterned. For example, the first metal source may be applied only on the portion of the surface of the substrate where the surface-treating composition is patterned. Thus, a metal layer may be formed only on the portion of the surface of the substrate where the surface-treating composition is patterned.

The substrate may be sintered under a reducing atmosphere at a temperature of about 180° C. or lower, about 160° C. or lower, about 150° C. or lower, about 130° C. or lower, about 120° C. or lower, or about 100° C. or lower, or at about 50° C. to about 180° C., or about 75° C. to about 160° C. to form the patterned metal film. Also, as above, a second metal source may be disposed on the patterned metal film.

Hereinafter, an embodiment will be disclosed in further detail with reference to Experimental Examples.

### Example 1

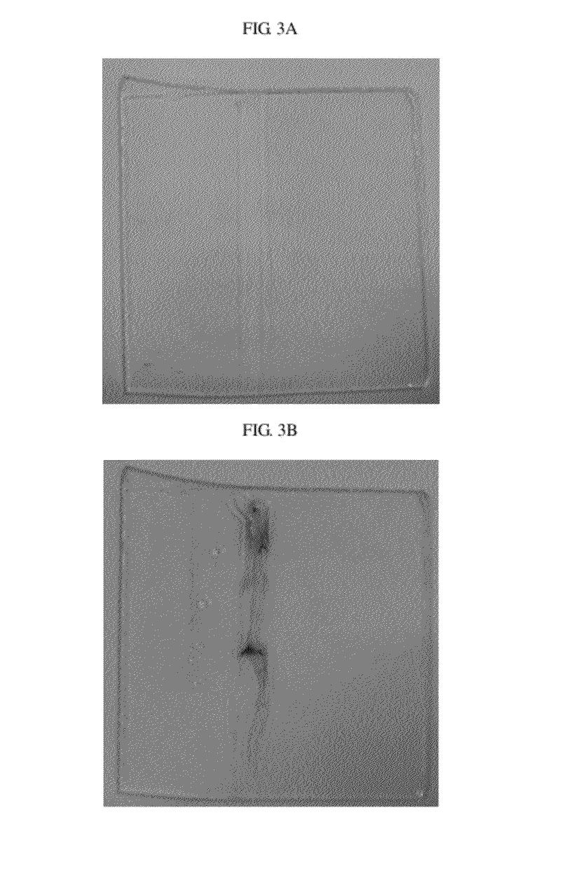

A 1 gram (g) quantity of ethyl cellulose and 0.03 g hydrazine are dissolved in 9 g toluene to prepare a surface-treating composition. The surface-treating composition is patterned on a glass plate by a printing process. FIG. 3A shows an image of the glass plate treated by the surface-treating composition. After 5 minutes, a polymer film is formed by sufficiently drying the surface-treating composition to remove the solvent, and then Ag precursor ink (10 weight percent (wt %) silver 2-ethyl-hexanoate in acetonitrile (MeCN)) is applied onto the glass plate in a thickness of about 20 micrometers (μm). Referring to FIG. 3B, it can be seen that the glass plate is discolored by reduction of Ag ions in the Ag precursor ink. The Ag precursor ink is further applied and sintered for about 2 minutes under an ambient atmosphere at a temperature of about 200° C. Referring to FIG. 3C, after sintering, it can be seen that intermediate and edge portions of the patterned portion have the same thickness, thus dewetting does not occur. The images of FIGS. 3A to 3C are obtained by a macroscopic observation method.

### Example 2

Copper formate (Cu(HCOO)₂) is dissolved in hexylamine (C₆H₁₅N) in a molar ratio of 1:1 to prepare a Cu precursor ink. Example 2 is performed by the same method as in Example 1, except that the Cu precursor ink is used instead of the Ag precursor ink.

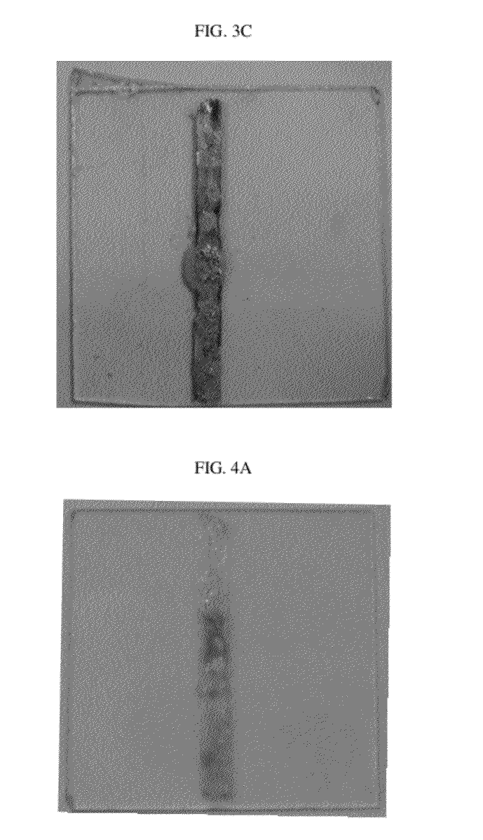

FIG. 4A shows an image of a glass plate on which the Cu precursor ink is applied. FIG. 4B shows an image of a glass plate on which the Cu precursor ink is further applied and sintered. Referring to FIG. 4B, it can be seen that intermediate and edge portions of a patterned portion have the same thickness, thus dewetting does not occur. The images of FIGS. 4A and 4B are obtained by a macroscopic observation method.

### Example 3

Example 3 is performed by the same method as in Example 1, except that 1 g of polyvinylpyrrolidone (“PVP”), 3 g carbazate, and 15 g ethylene glycol are used instead of 1 g ethyl cellulose, 0.03 g hydrazine, and 9 g toluene.

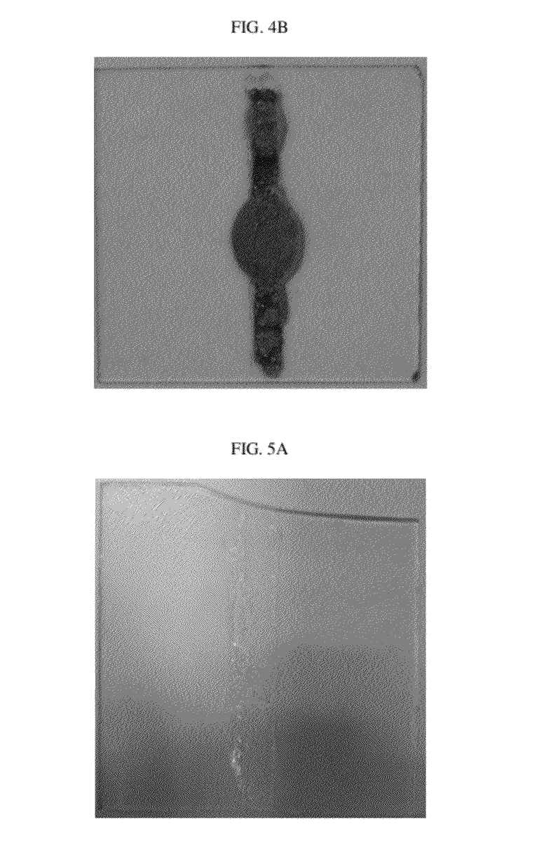

FIG. 5A shows an image of a glass plate on which the Ag precursor ink is applied. FIG. 5B shows an image of a glass plate on which the Ag precursor ink is further applied and sintered. Referring to FIG. 5B, it can be seen that intermediate and edge portions of a patterned portion have the same thickness, thus dewetting does not occur. FIGS. 5A and 5B are obtained by a macroscopic observation method.

### Example 4

A polymer-bonded reductant comprising polystyrene and according to Formula 3 is prepared. First, 30 milliliters (ml) dichloromethane is put in 1 g polystyrene having a molecular weight of 10,000 Daltons, 5 ml chloromethyl methyl ether is added, a catalytic amount of a 1 ml tetrahydrofuran (“THF”) solution containing 5 mg zinc dichloride (ZnCl₂) is added, and then the resulting mixture is stirred at a temperature of about 50° C. for 12 hours. Afterwards, the mixture is filtered to recover a polymer resin, and the polymer resin residue is washed with THF, THF-water (H₂O) (1:1), THF-hydrogen chloride (HCl), and hot water to remove remaining Cl ions. A 15 ml quantity of dimethylformamide (“DMF”) is added to 1 g of the chloromethylated polystyrene resin prepared above, 1 ml ethylenediamine (“EDA”) and 0.3 ml pyridine are added, and the resulting mixture is stirred. A resin is recovered by filtration about 15 hours later, and the residue is washed with 3×10 ml DMF, 3×10 ml DMF-methanol (1:1), and 3×10 ml methanol. Finally, the residue is washed with 3×10 ml water to remove the remaining EDA and Cl ions. A 20 ml quantity of NMP is added to 1 g of the obtained aminated resin, a 2 ml concentrated HCl solution is added, and the obtained mixture is stirred for 6 hours. A resin is filtered again, and the residue is washed with a sufficient amount of water (3×30 ml) to remove the remaining HCl and Cl ions. The obtained resin is dried in a vacuum, and 0.5 g dried resin is mixed with 5 ml DMF. A 0.2 g quantity of sodium borohydride (NaBH₄) is added, and the mixture is stirred for about 5 hours. After a reaction is finished, a resin is filtered, and the residue is washed with 3×10 ml DMF, 3×10 ml DMF-H₂O (1:1), and 3×10 ml water. Finally, the residue is washed with 30 ml methanol and dried at a temperature of about 50° C.

THF is added to 0.3 g of the finally obtained resin to produce a 10 g solution, and a 3% by weight solution is used to form a patterned film.

### Comparative Example 1

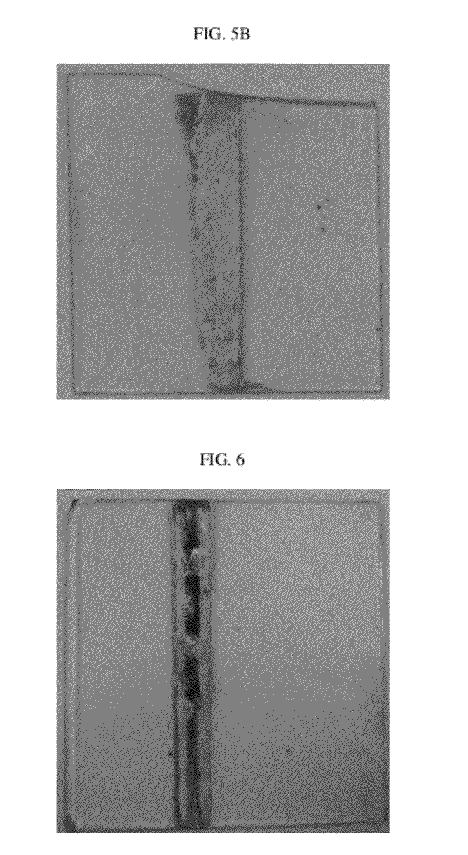

The same method is performed as in Example 1, except that hydrazine is not used. Referring to FIG. 6, as compared with FIG. 3C, it can be seen that intermediate and edge portions of a patterned portion have different thicknesses, thus dewetting occurred. The image of FIG. 6 is obtained by a macroscopic observation method.

According to the Examples, when a metal film is patterned using ink or a metal ion compound solution, dewetting does not occur. Also, according to an exemplary embodiment, a narrow linewidth of about 10 μm can be provided.

While exemplary embodiments have been disclosed herein, it should be understood that other variations may be possible. Such variations are not to be regarded as a departure from the spirit and scope of exemplary embodiments of the present application, and all such modifications as would be obvious to one skilled in the art are intended to be included within the scope of the following claims.

What is claimed is:

1. A method of patterning a metal to form a patterned metal film, the method comprising:
patterning a surface-treating composition comprising a polymer and a reductant on a surface of a substrate; and
applying a first metal source onto the substrate to form the patterned metal film.

2. The method according to claim 1, wherein the polymer and the reductant are bonded to each other in the surface-treating composition.

3. The method according to claim 1, wherein the first metal source comprises a precursor ink which comprises a metal, and the first metal source is applied on a portion of the surface of the substrate where the surface-treating composition is patterned.

4. The method according to claim 1, further comprising reducing the patterned metal film.

5. The method according to claim 1, further comprising applying a second metal source onto the patterned metal film and sintering the second metal source.

6. The method according to claim 5, wherein the second metal source is applied on at least one selected from an entire surface of the substrate, a portion of the substrate where the surface-treating composition is patterned, and the patterned metal film.

7. The method according to claim 1, wherein the surface-treating composition is patterned to have a linewidth of about 200 to about 5 micrometers.

8. The method according to claim 1, wherein the polymer is selected from a hydrophilic polymer, a hydrophobic polymer, and an amphipathic polymer.

9. The method according to claim 1, wherein the polymer includes at least one selected from ethyl cellulose, polystyrene, and polyvinyl pyrrolidone.

10. The method according to claim 1, wherein the polymer has at least one shape selected from a spherical shape, a bead shape, and a porous shape.

11. The method according to claim 1, wherein the reductant includes at least one selected from hydrazine, lithium aluminum hydride, alkyl aluminum hydride, sodium borohydride, zinc borohydride, trialkyl tin hydride, alkyl silane, a combination thereof, and a complex thereof.

12. The method according to claim 1, wherein the substrate includes at least one selected from a glass, a metal, a semiconductor, a ceramic, and a plastic.

13. The method according to claim 1, wherein the first metal source includes at least one selected from a metal precursor ink, a metal powder ink, and a metal paste.

14. The method according to claim 1, wherein the first metal source is metal precursor ink, and
wherein the metal precursor ink comprises at least one selected from an organo-metallic compound having a carbon-metal bond, a metal-organic compound containing an organic ligand and comprising a bond between a non-carbon element selected from oxygen, nitrogen, and sulfur with a metal, and an inorganic compound.

15. The method according to claim 14, wherein the inorganic compound includes at least one selected from a metal nitride, a metal halide, a metal sulfide, a metal hydroxide, and a metal carbonate.

16. An assembly for forming a patterned metal film, the assembly comprising:
a substrate;
a surface-treating composition patterned on the substrate; and
a first metal source disposed on the surface-treating composition.

17. The assembly according to claim 16, wherein the first metal source forms a metal layer on a portion of the substrate where the surface-treating composition is patterned.
